(19) United States
(12) Patent Application Publication
(10) Pub. No.: US 2008/0123200 A1
(43) Pub. Date: May 29, 2008

(54) Method and device for forming poly-silicon film

(75) Inventors: Fang-Tsun Chu, Taichung County (TW); Jia-Xing Lin, Taipei County (TW)

Correspondence Address: BIRCH STEWART KOLASCH & BIRCH, PO BOX 747, FALLS CHURCH, VA, 22040-0747, US

(73) Assignee: INDUSTRIAL TECHNOLOGY RESEARCH INSTITUTE

(21) Appl. No.: 11/826,963

(22) Filed: Jul. 19, 2007

(30) Foreign Application Priority Data
Jul. 13, 2006 (TW) 095125717

(51) Int. Cl. G02B 9/00; H01L 21/763

(52) U.S. Cl. 359/738; 438/487; 257/E21.572

(57) ABSTRACT

A method and a device for forming a poly-silicon film, using sequential lateral solidification (SLS) by laser irradiation through an optical device to pattern the laser beam so as to lengthen the crystalline grains and enhance the throughput. The optical device comprises a plurality of first transparent regions, a plurality of second transparent regions and a plurality of final transparent regions. The plurality of second transparent regions are disposed between the plurality of first transparent regions and the plurality of final transparent regions. The first transparent regions and the second transparent regions have a first width W1 and a first length L1, and the final transparent regions have a second width W2 and a second length L2. An m^{th} first transparent region of the plurality of first transparent regions and an m^{th} second transparent region of the plurality of second transparent regions are arranged in a tier-shape. An m^{th} final transparent region of the plurality of final transparent regions is extended from the m^{th} second transparent region of the plurality of second transparent regions.

### BACKGROUND OF THE INVENTION

1. Field of the Invention

The present invention generally relates to a method and a device for forming a film and, more particularly, to a method and a device for forming a poly-silicon (p-Si) film.

2. Description of the Prior Art

In semiconductor manufacturing, amorphous silicon (a-Si) thin-film transistors (TFTs) are now widely used in the liquid crystal display (LCD) industry because amorphous silicon films can be deposited on a glass substrate at low temperatures. However, the carrier mobility in an amorphous silicon film is much lower than that in a poly-silicon (p-Si) film, so that conventional amorphous silicon TFT-LCDs exhibit low driving current that limits applications for LCD devices with high integrated circuits. Accordingly, there have been lots of reports on converting low-temperature deposited amorphous silicon films into poly-silicon films using laser crystallzation.

Presently, poly-silicon films are gradually used in advanced electronic devices such as solar cells, LCDs and organic light-emitting devices (OLEDs). The quality of a poly-silicon film depends on the size of the poly-silicom grains that form the poly-silicon film. It is thus the greatest challenge to manufacture poly-silicon films having large grains with high throughput.

FIG. 1A is a conventional system for forming a poly-silicon film using sequential lateral solidification (SLS). The system comprises: a laser generator 11 for generating a laser beam 12 and an optical device 13 disposed in a traveling path of the laser beam 12. The optical device 13 has a plurality of transparent regions 13a and a plurality of opaque regions 13b. The optical device 13 is implemented using a mask or a micro-slit array. Each of the plurality of transparent regions 13a is a stripe region with a width W. The laser beam 12 passing through the transparent regions 13a irradiates an amorphous silicon film 15 on the substrate 14 in back of the optical device 13 so as to melt the amorphous silicon film 15 in the stripe regions 15a with a width W. As the laser beam 12 is removed, the melted amorphous silicon film 15 in the stripe regions 15a starts to solidify and re-crystallize to form laterally grown silicon grains. Primary grain boundaries 16 parallel to a long side of the stripe regions 15a are thus formed at the center of the stripe regions 15a and a poly-silicon film is formed to have crystal grains with a grain length equal to a half of the width W, as shown in 1B.

U.S. Pat. No. 6,726,768 discloses a method for forming a poly-silicon film using sequential lateral solidification (SLS) with multiple laser irradiation processes. In U.S. Pat. No. 6,726,768, an optical device is used to pattern the laser beam and thus control the grain length, as shown in FIG. 2A and FIG. 2B.

In FIG. 2A, the optical device 20 comprises a plurality of first transparent regions 21, a plurality of second transparent regions 22 and a plurality of third transparent regions 23 so that an amorphous silicon film (not shown) on a substrate (not shown) in back of the optical device 20 undergoes three laser irradiation processes while moving relatively to the optical device 20 along X-axis. In FIG. 2B, it is given that each of the first, the second and the third transparent regions 21, 22 and 23 has a width W. An offset width OS appears between the first transparent regions 21 and the second transparent regions 22 and between the second transparent regions 22 and the third transparent regions 23, so that an overlapped width OL exists between the (m+1)^{th} transparent region 21(m+1) of the first transparent regions 21 and the m^{th} transparent region 23m of the third transparent regions 23. In the three laser irradiation processes, a first primary grain boundary obtained after SLS using the first laser irradiation process on the amorphous silicon film (not shown) on the substrate (not shown) in back of the optical device 20 is then melted by the second laser irradiation process so as to form a second primary grain boundary after SLS. Similarly, the second primary grain boundary is then melted by the third laser irradiation process so as to form a third primary grain boundary after SLS. Therefore, the distance λ between two adjacent third primary grain boundaries is λ=W+2OS−OL.

In practical cases, however, the system for forming a poly-silicon film in FIG. 1A can further comprise a projection lens apparatus (not shown) disposed on the traveling path of the laser beam 12 between the substrate 14 and the optical device 13. Given that the projection lens apparatus has an amplification factor of N, the grown poly-silicon film has crystal grains that have a grain length of λ/N=(W+2OS−OL)/N.

Similarly, more than three laser irradiation processes can be used with SLS in U.S. Pat. No. 6,726,768 so as to obtain a poly-silicon film that has longer crystal grains. For example, four laser irradiation processes can be used with SLS to obtain a poly-silicon film that has a grain length of λ/N=(W+3OS−OL)/N with a projection lens apparatus or λ=(W+3OS−OL) with no projection lens apparatus.

However, the manufacturing throughput of the method described above is low because the number of laser irradiation processes may increase, which results in longer manufacturing time.

Therefore, there exists a need in providing a method and device for forming a poly-silicon film using sequential lateral solidification (SLS) by laser irradiation through an optical device to pattern the laser beam passing through the optical device so as to lengthen the poly-silicon grains and enhance manufacturing throughput while the number of laser irradiation processes is the same as the prior-art references.

### SUMMARY OF THE INVENTION

The present invention provides a method and a device for forming a poly-silicon (p-Si) film using sequential lateral solidification by laser irradiation through an optical device to pattern the laser beam passing through the optical device so as to lengthen the poly-silicon grains while the number of laser irradiation processes is the same as the prior-art references.

The present invention provides a method and a device for forming a poly-silicon (p-Si) film sequential lateral solidification by laser irradiation through an optical device to pattern the laser beam passing through the optical device so as to enhance manufacturing throughput while the number of laser irradiation processes is the same as the prior-art references.

The present invention provides a method for forming a poly-silicon (p-Si) film, the method comprising steps of:
(a) providing a substrate with an amorphous silicon film formed thereon;
(b) performing a first laser irradiation process on the substrate using a laser beam irradiating through an optical device, wherein the optical device comprises a plurality of first transparent regions, a plurality of second transparent regions and a plurality of final transparent regions, the plurality of second transparent regions being disposed between the plurality of first transparent regions and the plurality of final transparent regions, each of the first transparent regions and the second transparent regions having a first width W1 and a first length L1, and each of the final transparent regions having a second width W2 and a second length L2, an m^{th} first transparent region of the plurality of first transparent regions and an m^{th} second transparent region of the plurality of second transparent regions being arranged in a tier-shape, an m^{th} final transparent region of the plurality of final transparent regions being extended from the m^{th} second transparent region of the plurality of second transparent regions;
(c) moving the substrate for a first distance no longer than the first length L1;
(d) performing a second laser irradiation process on the substrate using the laser beam irradiating through the optical device;
(e) moving the substrate for a second distance no longer than the first length L1; and
(f) performing a final laser irradiation process on the substrate using the laser beam irradiating through the optical device so as to form poly-silicon regions with a final grain length in the amorphous silicon film.

The present invention further provides an optical device for forming a poly-silicon film, the optical device comprising:
a plurality of first transparent regions, a plurality of second transparent regions and a plurality of final transparent regions, the plurality of second transparent regions being disposed between the plurality of first transparent regions and the plurality of final transparent regions,
wherein each of the first transparent regions and the second transparent regions has a first width W1 and a first length L1, and each of the final transparent regions has a second width W2 and a second length L2,
wherein an m^{th} first transparent region of the plurality of first transparent regions and an m^{th} second transparent region of the plurality of second transparent regions are arranged in a tier-shape, an m^{th} final transparent region of the plurality of final transparent regions is extended from the m^{th} second transparent region of the plurality of second transparent regions.

### BRIEF DESCRIPTION OF THE DRAWINGS

The objects, spirits and advantages of the preferred embodiments of the present invention will be readily understood by the accompanying drawings and detailed descriptions, wherein:

FIG. 1A is a conventional system for forming a poly-silicon film using sequential lateral solidification (SLS);

FIG. 1B is a top view of a poly-silicon film formed using the system in FIG. 1A;

FIG. 2A is a top view of an optical device disclosed in U.S. Pat. No. 6,726,768;

FIG. 2B is an enlarged top view with detailed specification of the mask in FIG. 2A;

FIG. 3A is a top view of an optical device used in a method for forming a poly-silicon film according to a first embodiment of the present invention;

FIG. 3B is an enlarged top view with detailed specification of the mask in FIG. 3A;

FIG. 4 is a flow-chart showing a method for forming a poly-silicon film according to a second embodiment of the present invention;

FIG. 5A is a top view of an optical device used in a method for forming a poly-silicon film according to a second embodiment of the present invention;

FIG. 5B is an enlarged top view with detailed specification of the mask in FIG. 5A; and

FIG. 6 is a flow-chart showing a method for forming a poly-silicon film according to a second embodiment of the present invention.

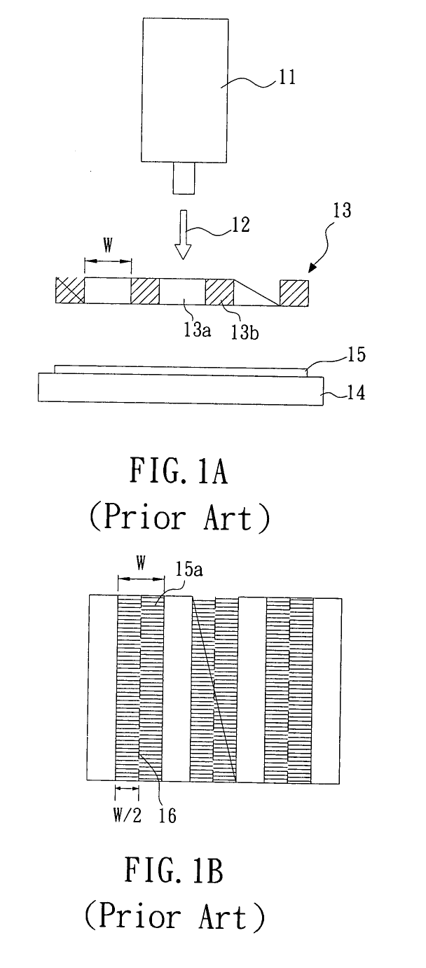

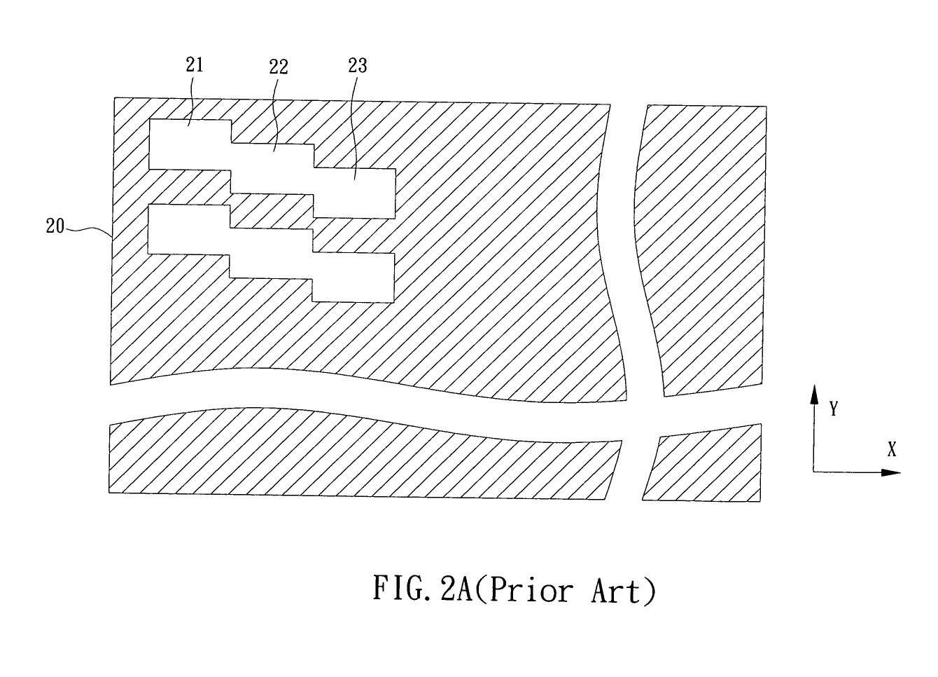

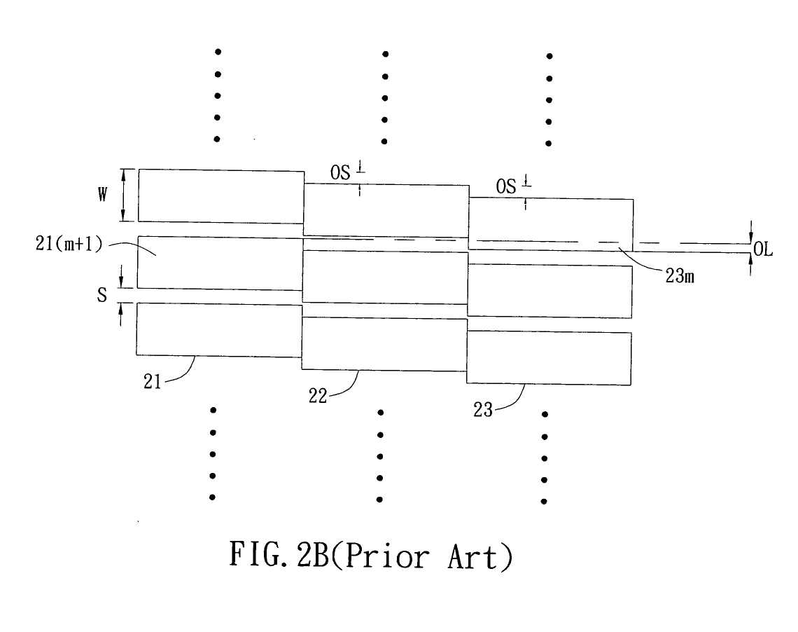

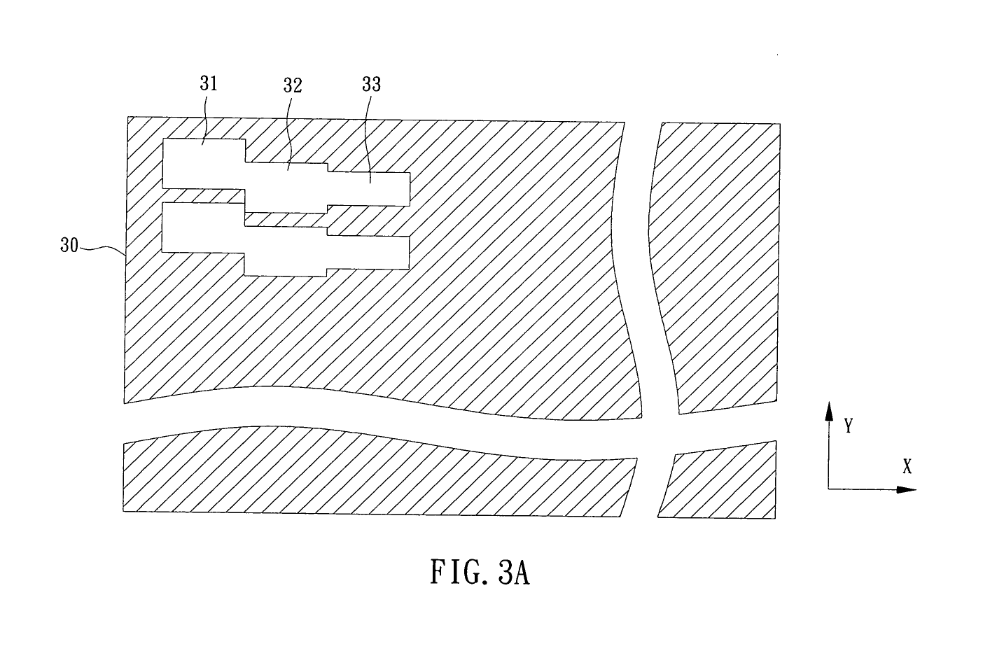

### DETAILED DESCRIPTION OF THE PREFERRED EMBODIMENT

The present invention providing a method and a device for forming a poly-silicon film can be exemplified by the preferred embodiments as described hereinafter.

In the present invention, sequential lateral solidification (SLS) by laser irradiation through an optical device is used to pattern the laser beam passing through the optical device so as to lengthen the poly-silicon grains and enhance manufacturing throughput while the number of laser irradiation processes is the same as the prior-art references.

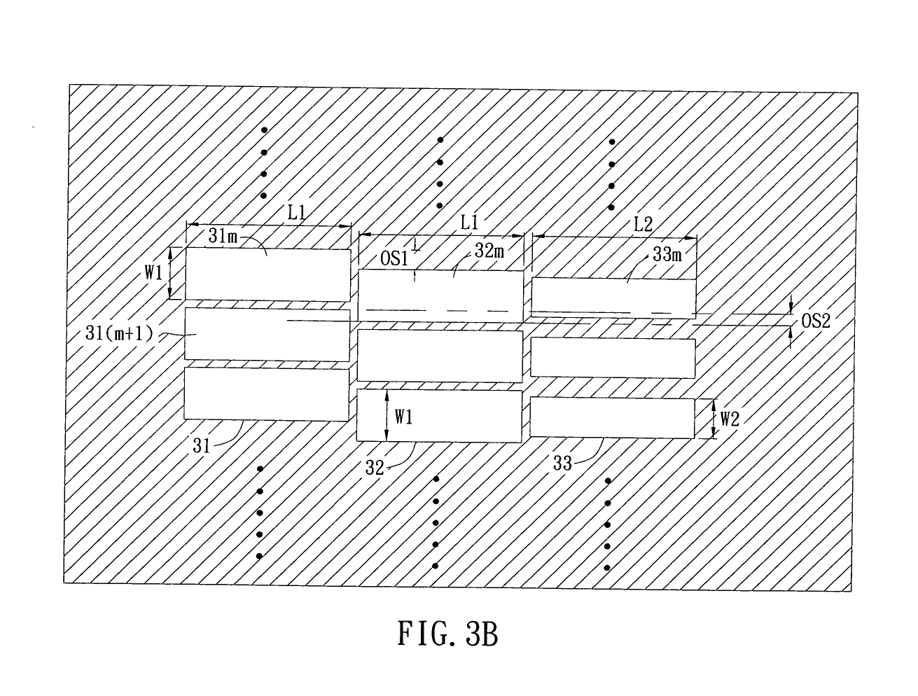

FIG. 3A and FIG. 3B are top views of an optical device used in a method for forming a poly-silicon film according to a first embodiment of the present invention. In FIG. 3A and FIG. 3B, the optical device 30 (for example, a mask or a micro-slit array) comprises a plurality of first transparent regions 31, a plurality of second transparent regions 32 and a plurality of final transparent regions 33. The plurality of second transparent regions 32 are disposed between the plurality of first transparent regions 31 and the plurality of final transparent regions 33. Each of the first transparent regions 31 and the second transparent regions 32 has a first width W1 and a first length L1. Each of the final transparent regions 33 has a second width W2 and a second length L2. An m^{th} first transparent region 31m of the plurality of first transparent regions 31 and an m^{th} second transparent region 32m of the plurality of second transparent regions 32 are arranged in a tier-shape. An m^{th} final transparent region 33m of the plurality of final transparent regions 33 is extended from the m^{th} second transparent region 32m of the plurality of second transparent regions 32.

During sequential lateral solidification (SLS), if the width W of each slit on the optical device 30 is smaller than twice the maximum grain length Wg using SLS with one laser irradiation through the optical device 30, a primary grain boundary is formed on the substrate corresponding to the center of the slit; however, if the width W of each slit on the optical device 30 is larger than twice the maximum grain length Wg using SLS with one laser irradiation through the optical device 30, a nucleus region with a width W−2Wg is formed on the substrate corresponding to the center of the slit. Therefore, in the present embodiment, the first width W1 is larger than twice the maximum grain length Wg using SLS with one laser irradiation through the optical device 30 such that W1>2Wg and the second width W2 is larger than W1−2Wg and smaller than 2Wg such that 2Wg>W2>(W1−2Wg).

In the present embodiment, a first offset width OS1 appears between the m^{th} first transparent region 31m and the m^{th} second transparent region 32m, and a second offset width OS2 appears between the (m+1)^{th} first transparent region 31(m+1) and the m^{th} second transparent region 32m such that OS2<OS1<Wg.

In practical cases, however, the optical device 30 for forming a poly-silicon film can be used with a projection lens apparatus (not shown) with an amplification factor N. The projection lens apparatus is disposed on the traveling path of the laser beam between the substrate and the optical device so as to improve the optical resolution during exposure. In this case, the first width W1 divided by the amplification factor N is larger than twice the maximum grain length Wg using sequential lateral solidification (SLS) with one laser irradiation through the optical device such that (W1/N)>2Wg and the second width W2 divided by the amplification factor N is larger than ((W1/N)−2Wg) and smaller than 2Wg such that 2Wg>(W2/N)>((W1/N)−2Wg). Moreover, a first offset width OS1 appears between the m^{th} first transparent region 31m and the m^{th} second transparent region 32m and a second offset width OS2 appears between the (m+1)^{th} first transparent region 31(m+1) and the m^{th} second transparent region 32m such that (OS2/N)<(OS1/N)<Wg.

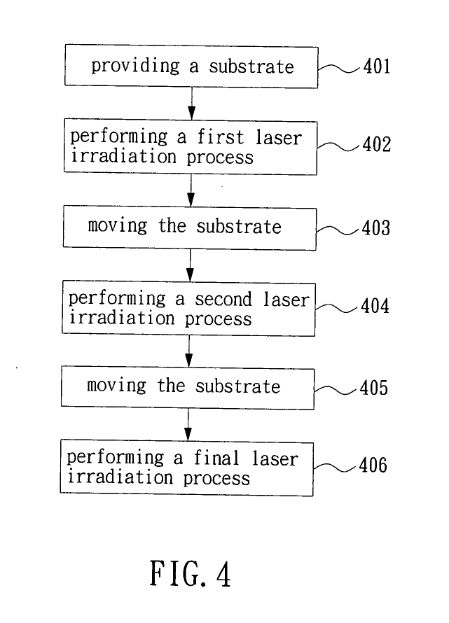

Therefore, the present invention provides a method for forming a poly-silicon film using the optical device 30 in FIG. 3A and FIG. 3B. The method comprises steps with reference to the steps described in FIG. 4, which is a flow-chart showing a method for forming a poly-silicon film according to a first embodiment of the present invention.

To begin with, as described in Step 401, a substrate with an amorphous silicon film (not shown) formed thereon is provided in back of the optical device 30 in the traveling path of a laser beam.

In Step 402, a first laser irradiation process is performed on the substrate using the laser beam irradiating through the optical device 30 so as to melt the amorphous silicon film in irradiated regions corresponding to the first transparent regions 31 on the optical device 30. Then, the laser beam is removed such that the melted amorphous silicon film in the irradiated regions solidifies by SLS to form poly-silicon regions with poly-silicon grains having a first grain length. Because the first width W1 of the first transparent regions 31 is larger than twice the maximum grain length Wg using SLS with one laser irradiation through the optical device 30, a nucleus region with a width W1−2Wg is formed on the substrate corresponding to the center of the slit. Meanwhile, the first grain length is Wg.

In Step 403, the substrate is moved for a first distance no longer than the first length L1 so that the poly-silicon film formed by SLS corresponds to the second transparent regions 32 on the optical device 30.

In Step 404, a second laser irradiation process is performed on the substrate using the laser beam irradiating through the optical device 30 so as to melt the amorphous silicon film and the solidified poly-silicon film in irradiated regions corresponding to the second transparent regions 32 on the optical device 30. The laser beam is then removed such that the melted silicon film in the irradiated regions solidifies by SLS to form poly-silicon regions.

In Step 405, the substrate is moved for a second distance no longer than the first length L1 so that the poly-silicon film formed by SLS corresponds to the final transparent regions 33 on the optical device 30.

In Step 406, a final laser irradiation process is performed on the substrate using the laser beam irradiating through the optical device 30 so as to melt the amorphous silicon film and the solidified poly-silicon film in irradiated regions corresponding to the final transparent regions 33 on the optical device 30. The laser beam is then removed such that the melted silicon film in the irradiated regions solidifies by SLS to form poly-silicon regions with a final grain length.

Since the second width W2 of the final transparent regions 33 is smaller than twice the maximum grain length Wg using SLS with one laser irradiation through the optical device 30, a primary grain boundary is formed on the substrate corresponding to the center of the slit. Meanwhile, the final grain length is λ=W2+3OS1−OS2.

In practical cases, however, the optical device can be used with a projection lens apparatus (not shown) with an amplification factor N. The projection lens apparatus is disposed on the traveling path of the laser beam between the substrate and the optical device so as to improve the optical resolution during exposure. If the amplification factor is N, the grain length of the poly-silicon film on the substrate is λ/N=(W2+3OS1−OS2)/N.

Accordingly, in the present embodiment, the grain length of the poly-silicon film is the distance between two primary grain boundaries after the final laser irradiation process λ=(W2+3OS1−OS2) without using any projection lens apparatus and λ/N=(W2+3OS1−OS2)/N when using a projection lens apparatus.

Compared to the prior references (W1=W2<Wg), the present embodiment results in a poly-silicon film having poly-silicon grains with a grain length λ=(W2+3OS1−OS2) under three laser irradiations, which is longer than the prior references. Therefore, the present embodiment can be used to manufacture poly-silicon films having poly-silicon grains with a longer length while the number of laser irradiation processes is the same as the prior-art references.

Even though the present invention is described with reference to the first embodiment, the present invention is not limited to the first embodiment and people with ordinary skills in the art can make various modifications within the scope of the present invention.

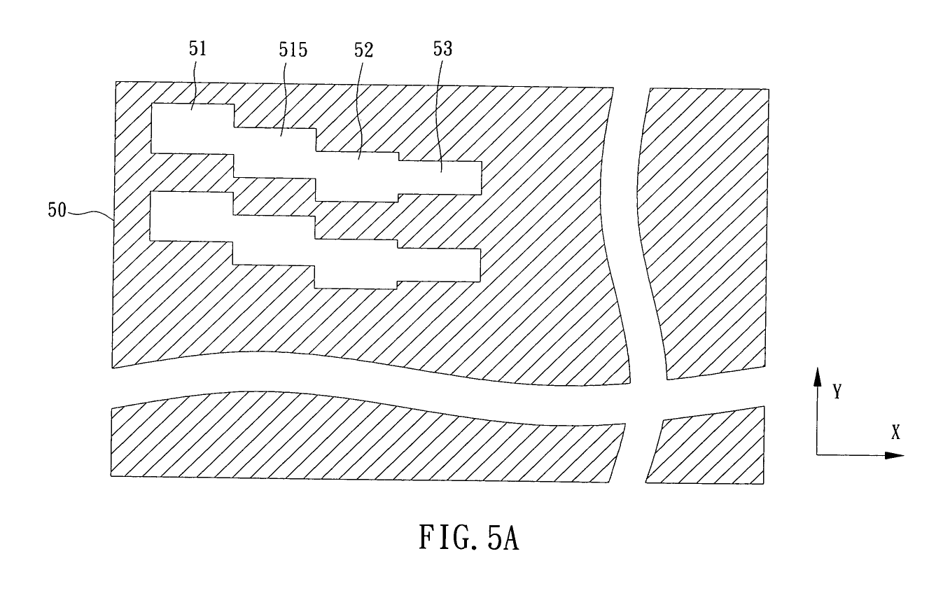

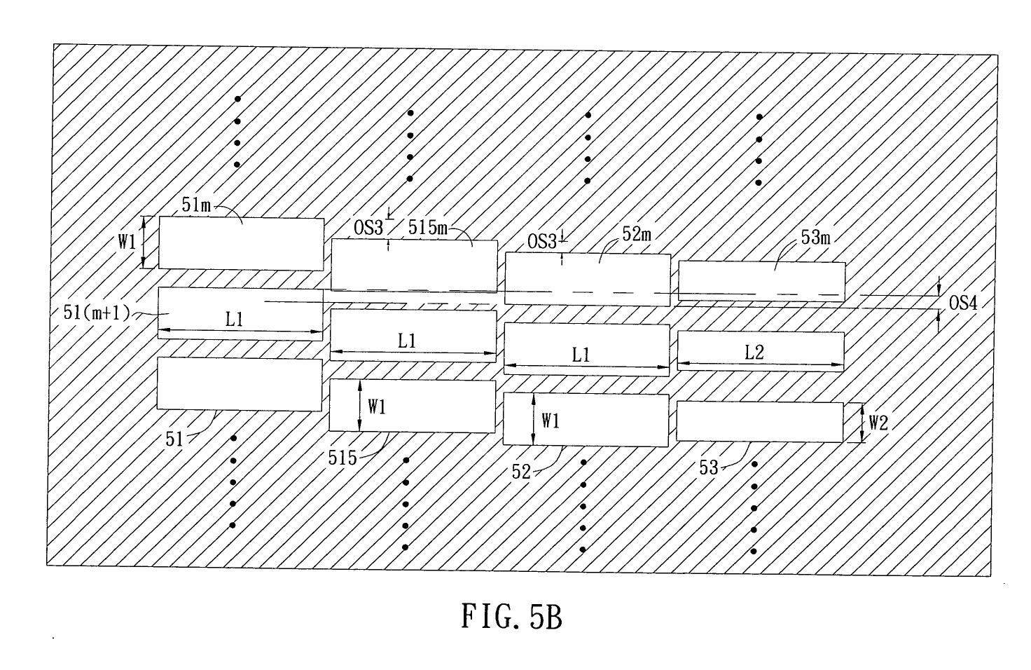

For example, FIG. 5A and FIG. 5B are top views of an optical device used in a method for forming a poly-silicon film according to a second embodiment of the present invention. In FIG. 5A and FIG. 5B, the optical device 50 (for example, a mask or a micro-slit array) comprises a plurality of first transparent regions 51, at least a plurality of extended transparent regions 515, a plurality of second transparent regions 52 and a plurality of final transparent regions 53. Each of the first transparent regions 51, the extended transparent regions 515 and the second transparent regions 52 has a first width W1 and a first length L1, so that an m^{th} first transparent region 51m of the plurality of first transparent regions 51, an m^{th} extended transparent region 515m of the plurality of extended transparent regions 51 and an m^{th} second transparent region 52m of the plurality of second transparent regions 52 are arranged in a tier-shape. Each of the final transparent regions 53 has a second width W2 and a second length L2. An m^{th} final transparent region 53m of the plurality of final transparent regions 53 is extended from the m^{th} second transparent region 52m of the plurality of second transparent regions 52.

During sequential lateral solidification (SLS), if the width W of each slit on the optical device 50 is smaller than twice the maximum grain length Wg using SLS with one laser irradiation through the optical device 50, a primary grain boundary is formed on the substrate corresponding to the center of the slit; however, if the width W of each slit on the optical device 50 is larger than twice the maximum grain length Wg using SLS with one laser irradiation through the optical device 50, a nucleus region with a width W−2Wg is formed on the substrate corresponding to the center of the slit. Therefore, in the present embodiment, the first width W1 is larger than twice the maximum grain length Wg using SLS with one laser irradiation through the optical device 50 such that W1>2Wg and the second width W2 is larger than W1−2Wg and smaller than 2Wg such that 2Wg>W2>(W1−2Wg).

In the present embodiment, a third offset width OS3 appears between the m^{th} first transparent region 51m and the m^{th} extended transparent region 515m and between the m^{th} extended transparent region 515m and the m^{th} second transparent region 52m and a fourth offset width OS4 appears between the (m+1)^{th} first transparent region 51(m+1) and the m^{th} second transparent region 52m such that OS4<OS3<Wg.

In practical cases, however, the optical device 50 can be used with a projection lens apparatus (not shown) with an amplification factor N. The projection lens apparatus is disposed on the traveling path of the laser beam between the substrate and the optical device so as to improve the optical resolution during exposure. In this case, the first width W1 divided by the amplification factor N is larger than twice the maximum grain length Wg using sequential lateral solidification (SLS) with one laser irradiation through the optical device such that (W1/N)>2Wg and the second width W2 divided by the amplification factor N is larger than ((W1/N)−2Wg) and smaller than 2Wg such that 2Wg>(W2/N)>((W1/N)−2Wg). Moreover, a third offset width OS3 appears between the m^{th} first transparent region 51m and the m^{th} extended transparent region 515m and between the m^{th} extended transparent region 515m and the m^{th} second transparent region 52m and a fourth offset width OS4 appears between the (m+1)^{th} first transparent region 51(m+1) and the m^{th} second transparent region 52m such that (OS4/N)<(OS3/N)<Wg.

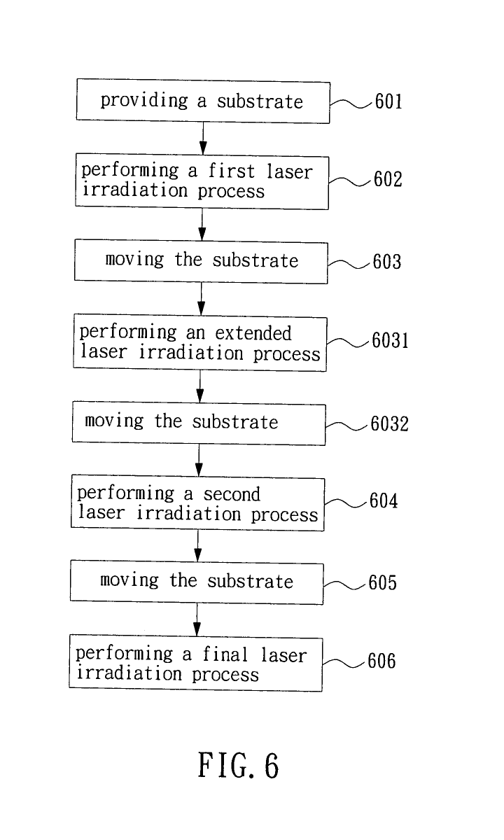

Therefore, the present invention provides a method for forming a poly-silicon film using the optical device 50 in FIG. 5A and FIG. 5B. The method comprises steps with reference to the steps described in FIG. 6, which is a flow-chart showing a method for forming a poly-silicon film according to a second embodiment of the present invention.

To begin with, as described in Step 601, a substrate with an amorphous silicon film (not shown) formed thereon is provided in back of the optical device 50 in the traveling path of a laser beam.

In Step 602, a first laser irradiation process is performed on the substrate using the laser beam irradiating through the optical device 50 so as to melt the amorphous silicon film in irradiated regions corresponding to the first transparent regions 51 on the optical device 50. Then, the laser beam is removed such that the melted amorphous silicon film in the irradiated regions solidifies by SLS to form poly-silicon regions with poly-silicon grains having a first grain length. Because the first width W1 of the first transparent regions 51 is larger than twice the maximum grain length Wg using SLS with one laser irradiation through the optical device 50, a nucleus region with a width W1−2Wg is formed on the substrate corresponding to the center of the slit. Meanwhile, the first grain length is Wg.

In Step 603, the substrate is moved for a first distance no longer than the first length L1 so that the poly-silicon film formed by SLS corresponds to the extended transparent regions 515 on the optical device 50.

In Step 6031, an extended laser irradiation process is performed on the substrate using the laser beam irradiating through the optical device 50 so as to melt the amorphous silicon film and the solidified poly-silicon film in irradiated regions corresponding to the extended transparent regions 515 on the optical device 50. Then, the laser beam is removed such that the melted silicon film in the irradiated regions solidifies by SLS to form poly-silicon regions with poly-silicon grains.

In Step 6032, the substrate is moved for an extended distance no longer than the first length L1 so that the poly-silicon film formed by SLS corresponds to the second transparent regions 52 on the optical device 50.

In Step 604, a second laser irradiation process is performed on the substrate using the laser beam irradiating through the optical device 50 so as to melt the amorphous silicon film and the solidified poly-silicon film in irradiated regions corresponding to the second transparent regions 52 on the optical device 50. The laser beam is then removed such that the melted silicon film in the irradiated regions solidifies by SLS to form poly-silicon regions.

In Step 605, the substrate is moved for a second distance no longer than the first length L1 so that the poly-silicon film formed by SLS corresponds to the final transparent regions 53 on the optical device 50.

In Step 606, a final laser irradiation process is performed on the substrate using the laser beam irradiating through the optical device 50 so as to melt the amorphous silicon film and the solidified poly-silicon film in irradiated regions corresponding to the final transparent regions 53 on the optical device 50. The laser beam is then removed such that the melted silicon film in the irradiated regions solidifies by SLS to form poly-silicon regions with a final grain length. Since the final width W2 of the final transparent regions 53 is smaller than twice the maximum grain length Wg using SLS with one laser irradiation through the optical device 50, a primary grain boundary is formed on the substrate corresponding to the center of the slit. Meanwhile, the final grain length is λ=W2+4OS1−OS2.

In practical cases, however, the optical device can be used with a projection lens apparatus (not shown) with an amplification factor N. The projection lens apparatus is disposed on the traveling path of the laser beam between the substrate and the optical device so as to improve the optical resolution during exposure. If the amplification factor is N, the grain length of the poly-silicon film on the substrate is λ/N=(W2+4OS1−OS2)/N.

Accordingly, in the present embodiment, the grain length of the poly-silicon film is the distance between two primary grain boundaries after the final laser irradiation process λ=(W2+4OS1−OS2) without using any projection lens apparatus any λ/N=(W2+4OS1−OS2)/N when using a projection lens apparatus.

Compared to the prior references (W1=W2<Wg), the present invention results in a poly-silicon film having poly-silicon grains with a grain length λ=(W2+4OS1−OS2) under four laser irradiations, which is longer than the prior references. Therefore, the present can be used to manufacture poly-silicon films having poly-silicon grains with a longer length while the number of laser irradiation processes is the same as the prior-art references.

According to the above discussion, it is apparent that the present invention discloses a method and a device for forming a poly-silicon film using sequential lateral solidification (SLS) by laser irradiation through an optical device (for example, a mask or a micro-slit array) to pattern the laser beam so as to lengthen the poly-silicon grains and enhance manufacturing throughput while the number of laser irradiation processes is the same as the prior-art references. Therefore, the present invention is novel, useful and non-obvious.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A method for forming a poly-silicon film, the method comprising steps of:
(a) providing a substrate with an amorphous silicon film formed thereon;
(b) performing a first laser irradiation process on the substrate using a laser beam irradiating through an optical device, wherein the optical device comprises a plurality of first transparent regions, a plurality of second transparent regions and a plurality of final transparent regions, the plurality of second transparent regions being disposed between the plurality of first transparent regions and the plurality of final transparent regions, each of the first transparent regions and the second transparent regions having a first width W1 and a first length L1, and each of the final transparent regions having a second width W2 and a second length L2, an m^{th} first transparent region of the plurality of first transparent regions and an m^{th} second transparent region of the plurality of second transparent regions being arranged in a tier-shape, an m^{th} final transparent region of the plurality of final transparent regions being extended from the m^{th} second transparent region of the plurality of second transparent regions;
(c) moving the substrate for a first distance no longer than the first length L1;
(d) performing a second laser irradiation process on the substrate using the laser beam irradiating through the optical device;
(e) moving the substrate for a second distance no longer than the first length L1; and
(f) performing a final laser irradiation process on the substrate using the laser beam irradiating through the optical device so as to form poly-silicon regions with a final grain length in the amorphous silicon film.

2. The method as recited in claim 1, wherein the optical device is a mask or a micro-slit array.

3. The method as recited in claim 1, wherein the first width W1 is larger than twice the maximum grain length Wg using sequential lateral solidification (SLS) with one laser irradiation through the optical device such that W1>2Wg and the second width W2 is larger than W1−2Wg and smaller than 2Wg such that 2Wg>W2>(W1−2Wg).

4. The method as recited in claim 3, wherein a first offset width OS1 appears between the mh first transparent region and the m^{th} second transparent region and a second offset width OS2 appears between the (m+1)^{th} first transparent region and the m^{th} second transparent region such that OS2<OS1<Wg.

5. The method as recited in claim 1, wherein the optical device is used with a projection lens apparatus with an amplification factor N, the projection lens apparatus being disposed on the traveling path of the laser beam between the substrate and the optical device.

6. The method as recited in claim 5, wherein the first width W1 divided by the amplification factor N is larger than twice the maximum grain length Wg using sequential lateral solidification (SLS) with one laser irradiation through the optical device such that (W1/N)>2Wg and the second width W2 divided by the amplification factor N is larger than ((W1/N)−2Wg) and smaller than 2Wg such that 2Wg>(W2/N)>((W1/N)−2Wg).

7. The method as recited in claim 6, wherein a first offset width OS1 appears between the m^{th} first transparent region and the m^{th} second transparent region and a second offset width OS2 appears between the (m+1)^{th} first transparent region and the m^{th} second transparent region such that (OS2/N)<(OS1/N)<Wg.

8. The method as recited in claim 1, further comprising between step (c) and step (d) steps of:
(c1) performing an extended laser irradiation process on the substrate using the laser beam irradiating through the optical device; and
(c2) moving the substrate for an extended distance no longer than the first length L1;
wherein the optical device further comprises at least a plurality of extended transparent regions disposed between the plurality of first transparent regions and the plurality of second transparent regions, each of the extended transparent regions having the first width W1 and the first length L1 so that the m^{th} first transparent region of the plurality of first transparent regions, an m^{th} extended transparent region of the plurality of extended transparent regions and the mh second transparent region of the plurality of second transparent regions are arranged in a tier-shape.

9. The method as recited in claim 8, wherein the optical device is a mask or a micro-slit array.

10. The method as recited in claim 8, wherein the first width W1 is larger than twice the maximum grain length Wg using sequential lateral solidification (SLS) with one laser irradiation through the optical device such that W1>2Wg and the second width W2 is larger than W1−2Wg and smaller than 2Wg such that 2Wg>W2>(W1−2Wg).

11. The method as recited in claim 10, wherein a third offset width OS3 appears between the m^{th} first transparent region and the m^{th} extended transparent region and between the m^{th} extended transparent region and the m^{th} second transparent region and a fourth offset width OS4 appears between the (m+1)^{th} first transparent region and the m^{th} second transparent region such that OS4<OS3<Wg.

12. The method as recited in claim 8, wherein the optical device is used with a projection lens apparatus with an amplification factor N, the projection lens apparatus being disposed on the traveling path of the laser beam between the substrate and the optical device.

13. The method as recited in claim 12, wherein the first width W1 divided by the amplification factor N is larger than twice the maximum grain length Wg using sequential lateral solidification (SLS) with one laser irradiation through the optical device such that (W1/N)>2Wg and the second width W2 divided by the amplification factor N is larger than ((W1/N)−2Wg) and smaller than 2Wg such that 2Wg>(W2/N)>((W1/N)−2Wg).

14. The method as recited in claim 13, wherein a third offset width OS3 appears between the m^{th} first transparent region and the m^{th} extended transparent region and between the m^{th} extended transparent region and the m^{th} second transparent region and a fourth offset width OS4 appears between the (m+1)^{th} first transparent region and the m^{th} second transparent region such that (OS4/N)<(OS3/N)<Wg.

15. An optical device for forming a poly-silicon film, comprising:
a plurality of first transparent regions, a plurality of second transparent regions and a plurality of final transparent regions, the plurality of second transparent regions being disposed between the plurality of first transparent regions and the plurality of final transparent regions,
wherein each of the first transparent regions and the second transparent regions has a first width W1 and a first length L1, and each of the final transparent regions has a second width W2 and a second length L2,
wherein an m^{th} first transparent region of the plurality of first transparent regions and an m^{th} second transparent region of the plurality of second transparent regions are arranged in a tier-shape, an m^{th} final transparent region of the plurality of final transparent regions is extended from the m^{th} second transparent region of the plurality of second transparent regions.

16. The optical device as recited in claim 15, wherein the optical device is a mask or a micro-slit array.

17. The optical device as recited in claim 15, wherein the first width W1 is larger than twice the maximum grain length Wg using sequential lateral solidification (SLS) with one laser irradiation through the optical device such that W1>2Wg and the second width W2 is larger than W1−2Wg and smaller than 2Wg such that 2Wg>W2>(W1−2Wg).

18. The optical device as recited in claim 17, wherein a first offset width OS1 appears between the m^{th} first transparent region and the m^{th} second transparent region and a second offset width OS2 appears between the (m+1)^{th} first transparent region and the m^{th} second transparent region such that OS2<OS1<Wg.

19. The optical device as recited in claim 15, wherein the optical device is used with a projection lens apparatus with an amplification factor N.

20. The optical device as recited in claim 19, wherein the first width W1 divided by the amplification factor N is larger than twice the maximum grain length Wg using sequential lateral solidification (SLS) with one laser irradiation through the optical device such that (W1/N)>2Wg and the second width W2 divided by the amplification factor N is larger than ((W1/N)−2Wg) and smaller than 2Wg such that 2Wg>(W2/N)>((W1/N)−2Wg).

21. The optical device as recited in claim 20, wherein a first offset width OS1 appears between the m^{th} first transparent region and the m^{th} second transparent region and a second offset width OS2 appears between the (m+1)^{th} first transparent region and the m^{th} second transparent region such that (OS2/N)<(OS1/N)<Wg.

22. The optical device as recited in claim 15, further comprising:
at least a plurality of extended transparent regions disposed between the plurality of first transparent regions and the plurality of second transparent regions, each of the extended transparent regions having the first width W1 and the first length L1 so that the m^{th} first transparent region of the plurality of first transparent regions, an m^{th} extended transparent region of the plurality of extended transparent regions and the m^{th} second transparent region of the plurality of second transparent regions are arranged in a tier-shape.

23. The optical device as recited in claim 22, wherein the optical device is a mask or a micro-slit array.

24. The optical device as recited in claim 22, wherein the first width W1 is larger than twice the maximum grain length Wg using sequential lateral solidification (SLS) with one laser irradiation through the optical device such that W1>2Wg and the second width W2 is larger than W1−2Wg and smaller than 2Wg such that 2Wg>W2>(W1−2Wg).

25. The optical device as recited in claim 24, wherein a third offset width OS3 appears between the m^{th} first transparent region and the m^{th} extended transparent region and between the m^{th} extended transparent region and the m^{th} second transparent region and a fourth offset width OS4 appears between the (m+1)^{th} first transparent region and the m^{th} second transparent region such that OS4<OS3<Wg.

26. The optical device as recited in claim 22, wherein the optical device is used with a projection lens apparatus with an amplification factor N.

27. The optical device as recited in claim 26, wherein the first width W1 divided by the amplification factor N is larger than twice the maximum grain length Wg using sequential lateral solidification (SLS) with one laser irradiation through the optical device such that (W1/N)>2Wg and the second width W2 divided by the amplification factor N is larger than ((W1/N)−2Wg) and smaller than 2Wg such that 2Wg>(W2/N)>((W1/N)−2Wg).

28. The optical device as recited in claim 27, wherein a third offset width OS3 appears between the m^{th} first transparent region and the mh extended transparent region and between the m^{th} extended transparent region and the m^{th} second transparent region and a fourth offset width OS4 appears between the (m+1)^{th} first transparent region and the m^{th} second transparent region such that (OS4/N)<(OS3/N)<Wg.
